(19) United States
(12) Patent Application Publication
(10) Pub. No.: US 2026/0198369 A1
(43) Pub. Date: Jul. 9, 2026

(54) ELECTRONIC DEVICE AND METHOD OF MANUFACTURING THE SAME

(71) Applicant: Advanced Semiconductor Engineering, Inc., Kaohsiung (TW)

(72) Inventors: Fan-Yu MIN, Kaohsiung (TW); Meng-Wei HSIEH, Kaohsiung (TW); Chao Wei LIU, Kaohsiung (TW)

(73) Assignee: Advanced Semiconductor Engineering, Inc., Kaohsiung (TW)

(21) Appl. No.: 19/286,186

(22) Filed: Jul. 30, 2025

Related U.S. Application Data
(60) Provisional application No. 63/743,590, filed on Jan. 9, 2025.

(51) Int. Cl. H01L 23/31; H01L 21/56; H01L 23/00; H01L 23/373; H01L 23/538; H01L 25/18; H10B 80/00; H10D 80/30

(52) U.S. Cl. CPC H10W 74/121; H10W 40/255; H10W 70/611; H10W 74/01; H10W 90/00; H10W 90/401; H10B 80/00; H10D 80/30; H10W 74/15; H10W 90/724; H10W 90/734

(57) ABSTRACT

The present disclosure provides an electronic device. The electronic device includes a metal-containing layer, a retaining structure disposed over the metal-containing layer, and an underfill connecting the metal-containing layer and the retaining structure. The retaining structure defines an opening over the metal-containing layer to accommodate a memory package. The underfill contacts a sidewall of the retaining structure. A method for manufacturing an electronic device is also provided.

### CROSS REFERENCE TO RELATED APPLICATION

This application claims the benefit of U.S. provisional application No. 63/743,590, filed Jan. 9, 2025, the content of which is incorporated herein by reference in its entirety.

### BACKGROUND

### 1. Technical Field

The present disclosure relates to an electronic device and a method of manufacturing an electronic device.

### 2. Description of the Related Art

A Fan-out Multi-Chip Module (FO-MCM) integrates multiple chips within a single encapsulant, using a redistribution layer (RDL) to fan out I/Os. However, traditional FO-MCMs can incur higher costs and lower yields, as damaged components cannot be removed or replaced once molding is complete.

### SUMMARY

In some arrangements, an electronic device includes a metal-containing layer, a retaining structure disposed over the metal-containing layer, and an underfill connecting the metal-containing layer and the retaining structure. The retaining structure defines an opening over the metal-containing layer to accommodate a memory package. The underfill contacts a sidewall of the retaining structure.

In some arrangements, an electronic device includes a metal-containing layer, a chip disposed over the metal-containing layer and having a backside surface, and a retaining structure disposed over the metal-containing layer and adjacent to the chip. The electronic device further includes an underfill connecting the metal-containing layer, the chip, and the retaining structure. A top surface of the retaining structure is substantially aligned with the backside surface of the chip.

In some arrangements, a method for manufacturing an electronic device includes providing a metal-containing layer, disposing a retaining structure over the metal-containing layer, forming a first encapsulant covering the retaining structure, and partially removing the retaining structure to form an allocate space defined by the retaining structure.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1B illustrates a partial enlarged view of an electronic device in accordance with some arrangements of the present disclosure.

FIG. 1C illustrates a cross-sectional view of an electronic device in accordance with some arrangements of the present disclosure.

FIG. 1D illustrates a partial enlarged view of an electronic device in accordance with some arrangements of the present disclosure.

FIG. 2A illustrates a cross-sectional view of an electronic device in accordance with some arrangements of the present disclosure.

FIG. 2B illustrates a cross-sectional view of an electronic device in accordance with some arrangements of the present disclosure.

FIG. 2C illustrates a cross-sectional view of an electronic device in accordance with some arrangements of the present disclosure.

FIG. 2D illustrates a partial enlarged view of an electronic device in accordance with some arrangements of the present disclosure.

FIG. 2E illustrates a partial enlarged view of an electronic device in accordance with some arrangements of the present disclosure.

FIG. 2F illustrates a partial enlarged view of an electronic device in accordance with some arrangements of the present disclosure.

FIGS. 3A, 3B, 3C, 3D, 3E, 3F, and 3G are cross-sections of one or more stages of a method of manufacturing an electronic device in accordance with some arrangements of the present disclosure.

FIGS. 4A, 4B, and 4C are cross-sections of one or more stages of a method of manufacturing an electronic device in accordance with some arrangements of the present disclosure.

### DETAILED DESCRIPTION

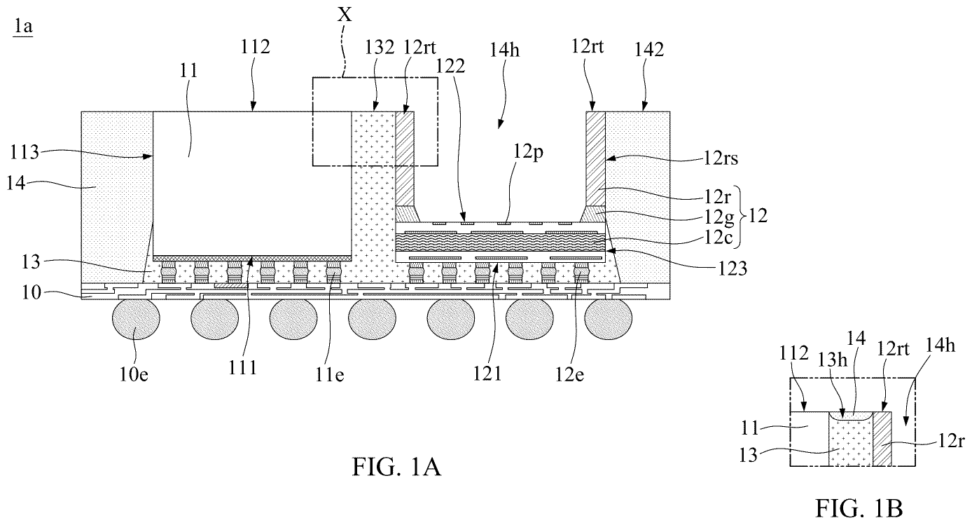

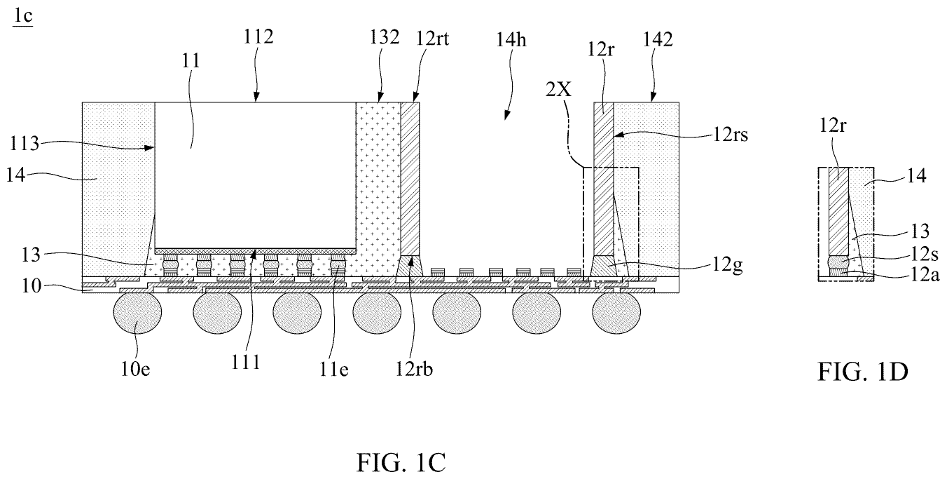

FIG. 1A illustrates a cross-sectional view of an electronic device 1a in accordance with some arrangements of the present disclosure. The electronic device 1a may include a package, such as an electronic device package. In some arrangements, the electronic device 1a may include a carrier 10, an electronic component 11, a component 12, an underfill 13, and an encapsulant 14.

The carrier 10 may be configured to provide structural support for the electronic component 11, the component 12, the underfill 13, and the encapsulant 14. In some arrangements, the carrier 10 may be configured to reroute or redistribute the input/output (I/O) connections of the electronic component 11 and the component 12 to a different layout that is more suitable for packaging or interconnection with other components. For example, the carrier 10 may be configured to reroute or redistribute the I/O connections of the electronic component 11 and the component 12 to a board (not illustrated in the figures) through electrical contacts 10e.

In some arrangements, the line spacing of the I/O connections of the electronic component 11 may be smaller or finer than that of the carrier 10. For example, the value range of the Line/Space (L/S) ratio of the I/O connections of the electronic component 11 may be smaller than that of the carrier 10. In some arrangements, the line spacing of the I/O connections of the component 12 may be smaller or finer than that of the carrier 10. For example, the value range of the L/S ratio of the I/O connections of the component 12 may be smaller than that of the carrier 10. In some arrangements, the line spacing of the I/O connections of the electronic component 11 may be different from that of the component 12.

The carrier 10 may include a metal-containing layer. The carrier 10 may include one or more redistribution layers (RDLs). For example, the carrier 10 may include one or more conductive layers and one or more dielectric layers. A portion of the conductive layer may be covered or encapsulated by the dielectric layer, while another portion of the conductive layer may be exposed from the dielectric layer to provide electrical connections. The conductive layer may include a conductive material such as a metal or metal alloy. Examples of the conductive materials include gold (Au), silver (Ag), copper (Cu), platinum (Pt), palladium (Pd), other metals or alloys, or a combination of two or more of these. The dielectric layer may include a dielectric material, such as an epoxy-based material (e.g., epoxy resin with silica/alumina fillers), a molding compound (e.g., an epoxy molding compound or another type of molding compound), Ajinomoto build-up film (ABF), polyimide (PI), benzocyclobutene (BCB), silicon oxide, silicon nitride, etc. In some arrangements, the dielectric layer may include other suitable non-conductive materials or insulating materials. For example, the dielectric layer may include a nano-composite material composed of a dielectric material with a nano-filler material dispersed throughout. The transparency of the nano-composite material may range from about fifty percent to about ninety percent, and the nano-filler material may be shaped as a sheet, rod, core-shell, or tube.

The electronic component 11 may be disposed over the carrier 10. The electronic component 11 may be electrically connected to the carrier 10, and the electrical connections may be attained by way of solder bonding, Cu-to-Cu bonding, wire bonding, or hybrid bonding. For example, the electronic component 11 may be electrically connected with the conductive layer of the carrier 10 through electrical contacts 11e. In some arrangements, the electronic component 11 may be electrically connected to the carrier 10 by a metal-to-metal bonding, without a separate bonding material.

The electronic component 11 may include a surface 111 facing the carrier 10, a surface 112 opposite to the surface 111, and a surface 113 extending between the surface 111 and the surface 112. The surface 111 may be an active surface, a front surface, or a front side. The surface 112 may be a backside surface or a backside. The surface 113 may be a lateral surface or a sidewall.

In some arrangements, the electronic component 11 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 11 may include a radio frequency integrated circuit (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. For example, the electronic component 11 may include a system on chip (SoC), a system-on-module (SoM), a system-in-package (SiP), or another type of IC that combines multiple components. Additionally, there may be any number of electronic components depending on design requirements.

The component 12 may be disposed over the carrier 10. The component 12 may be adjacent to the electronic component 11. The component 12 may be in the vicinity of the electronic component 11. In some arrangements, the distance (such as the shortest distance) between the component 12 and the electronic component 11 may be less than about 300 micrometers (μm). For example, the distance may be about 200 μm to 300 μm.

The component 12 may be electrically connected to the carrier 10, and the electrical connections may be attained by way of solder bonding, Cu-to-Cu bonding, wire bonding, or hybrid bonding. For example, the component 12 may be electrically connected with the conductive layer of the carrier 10 through electrical contacts 12e. In some arrangements, the component 12 may be electrically connected to the carrier 10 by a metal-to-metal bonding, without a separate bonding material.

In some arrangements, the electrical contacts 10e, 11e, and 12e may include solder balls or solder bumps, such as controlled collapse chip connection (C4) bumps, a ball grid array (BGA) or a land grid array (LGA).

The component 12 may include a carrier 12c and a retaining structure 12r. The retaining structure 12 r may be connected to the carrier 12 c through an adhesive layer 12g. The adhesive layer 12g may include a die attach film (DAF), a glue, a bonding layer, an underfill, or another suitable material.

The carrier 12c may be or include a substrate. The carrier 12c may be made of materials like silicon, polymer, polymer composite, metal, ceramic, glass, glass epoxy, or other semiconductor materials. The carrier 12c may include a surface 121 facing the carrier 10, a surface 122 opposite to the surface 121, and a surface 123 extending between the surface 121 and the surface 122. The surface 121 may be an active surface, a front surface, or a front side. The surface 122 may be a backside surface or a backside. The surface 123 may be a lateral surface or a sidewall.

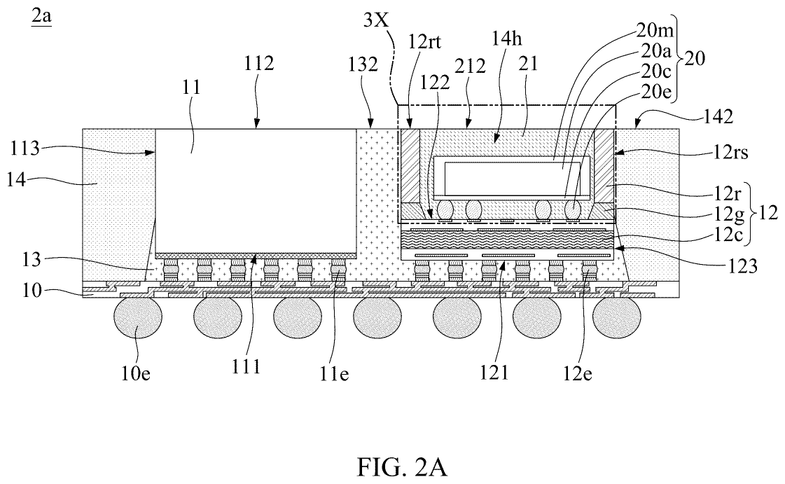

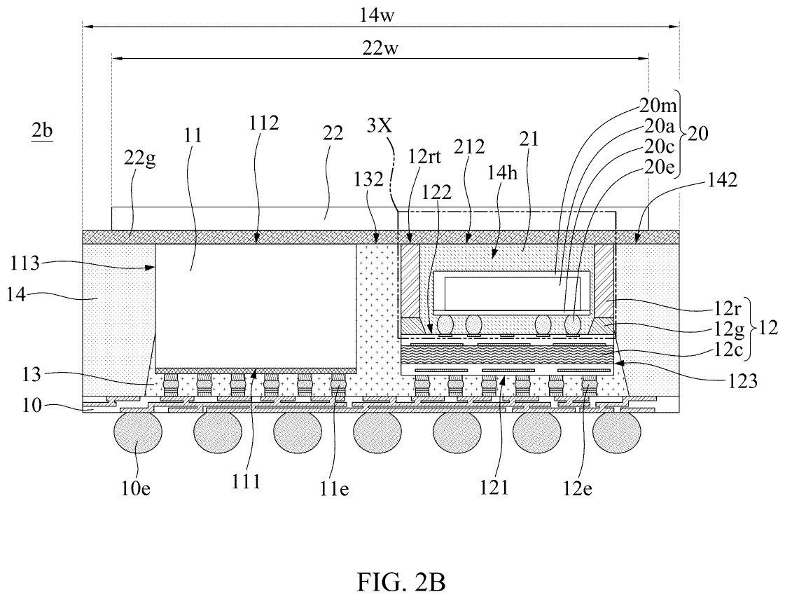

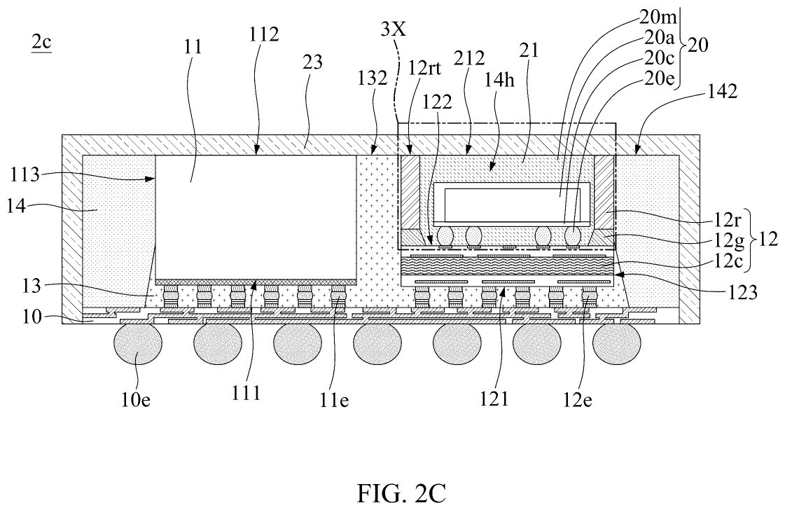

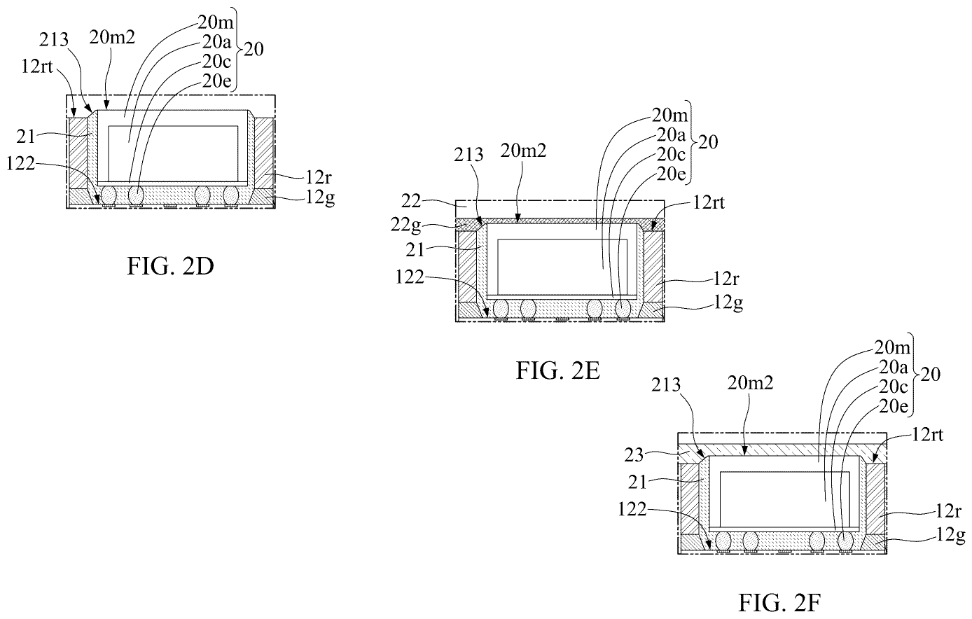

The surface 123 of the carrier 12c may face toward the surface 113 of the electronic component 11. The carrier 12c may include one or more conductive pads 12p disposed over the surface 122. The conductive pads 12p may be exposed on the surface 122. The conductive pads 12p may be configured to provide electrical connections for another component (such as the package 20 in FIG. 2A).

In some arrangements, the carrier 12c may include a logic die or an active component. In some arrangements, the carrier 12c may include control logic for managing memory operations. For example, the carrier 12c may be configured to communicate with a controller (such as the electronic component 11), receive commands, addresses, and data, and relay these commands, addresses, and data to another component (such as the package 20 in FIG. 2A).

For example, the carrier 12c may control or process the electrical signals actively. For example, the carrier 12c may perform functions such as amplifying, modulating, filtering, rectifying, switching, and/or converting the electrical signals that are either transmitted to or from the package 20. Specifically, the data transmitted to or from the package 20 may first undergo initial processing by the carrier 12c. Subsequently, the processed data can be further handled or analyzed by the electronic component 11. The electronic component 11 may be a slave in a master-slave configuration to the carrier 12c, wherein the carrier 12c provides control signals to the electronic component 11 through the carrier 10.

Alternatively, the data may first undergo initial processing by the electronic component 11, and then by the carrier 12c. This layered approach to signal processing enhances the overall system performance by ensuring that signals are optimized before reaching their final destination within the electronic architecture.

In some arrangements, the carrier 12c may include an interposer, a bridge, an electrical interface, or a passive component. For example, the carrier 12c may be a silicon interposer, a glass interposer, a ceramic interposer, or another suitable interposer. For example, the carrier 12c may include bridge metal coupling the package 20 to the carrier 10. For example, the carrier 12c may focus on providing robust and reliable location-based or protective functionalities without the complexities introduced by active circuitry. For example, the carrier 12c may exclude active devices such as transistors, diodes, ICs, operational amplifiers (op-amps), and similar devices.

In some arrangements, the carrier 12c may include active devices disposed in adjacent to the surface 121. In some arrangements, the carrier 12c may include a reconfigurable interposer that has desired circuit functions complementary to another component (such as the package 20 in FIG. 2A).

The retaining structure 12r be disposed over the carrier 12c. The retaining structure 12r may protrude from or extend outward away from the surface 122 of the carrier 12c. In some arrangements, the retaining structure 12r may be angled or oriented with respect to the surface 122 of the carrier 12c. For example, a tapering angle of the retaining structure 12r may be greater than 90 degrees. In some arrangements, the retaining structure 12 r be substantially vertical to the surface 122 of the carrier 12c. For example, the retaining structure 12r may have a lengthwise direction having a general trend substantially parallel to the surface 122 of the carrier 12c.

From the cross-sectional view, the retaining structure 12r may be disposed over the periphery region of the carrier 12c. The retaining structure 12r may define or have an opening 14h over the carrier 12c. The opening 14h may locate over the central region of the carrier 12c. The central region of the carrier 12c may be exposed from the opening 14h. The conductive pads 12p of the carrier 12c may be exposed from the opening 14h.

In some arrangements, from a top view, the retaining structure 12r may have a circular or rounded configuration or may exhibit a circular or rounded shape. For example, the retaining structure 12r may surround the opening 14h. For example, the retaining structure 12r may circle around the opening 14h. For example, the retaining structure 12r may completely encircle the opening 14h, providing a continuous boundary around it.

In some arrangements, the retaining structure 12r may be configured to prevent the encapsulant 14 and/or the underfill 13 from flowing or bleeding onto the carrier 12c, thereby avoiding the unintended coverage of the conductive pads 12p. This precaution helps to maintain the electrical integrity and functionality of the conductive pads 12p by ensuring they remain exposed and accessible for subsequent testing procedures or connections.

In some arrangements, the component 12 may be configured to predefine the location for placing another component (such as the package 20 in FIG. 2A). For example, the opening 14h may be configured to accommodate another component (such as the package 20 in FIG. 2A). For example, the opening 14h may be an allocate space for another component (such as the package 20 in FIG. 2A). For example, the component 12 may be configured to serve as a predefined location or mounting point for the package 20. This arrangement helps to reduce manufacturing costs and improve overall yield by designating an RDL area for die placement. Additionally, it allows the placement of package 20 to be postponed until after the molding operation is complete. By deferring this step, the process minimizes potential damage to the package 20 during molding and enhances the precision of die alignment, ultimately contributing to higher product reliability and efficiency.

The underfill 13 may be disposed between the carrier 10 and the electronic component 11. The underfill 13 may surround or cover the electrical contacts 11e. The underfill 13 may climb onto the surface 113 of the electronic component 11. The climbing height (or the vertical coverage height, or the extension length) of the underfill 13 may be vary. For example, the climbing height of the underfill 13 on the left side of the electronic component 11 may be less than that on the right side. In some arrangements, the surface 113 of the electronic component 11 may be entirely covered by the underfill 13. For example, the left side and/or the right side of the electronic component 11 may be entirely covered by the underfill 13.

The underfill 13 may be disposed between the carrier 10 and the component 12. The underfill 13 may surround or cover the electrical contacts 12e. The underfill 13 may climb onto the surface 123 of the carrier 12c and the surface (such as the external sidewall) 12rs of the retaining structure 12r. The climbing height (or the vertical coverage height, or the extension length) of the underfill 13 may be vary. For example, the climbing height of the underfill 13 on the left side of the carrier 12c may be greater than that on the right side. In some arrangements, the surface 123 of the carrier 12c may be entirely covered by the underfill 13. For example, the left side and/or the right side of the carrier 12c may be entirely covered by the underfill 13. In some arrangements, the surface 12rs of the retaining structure 12r may be entirely covered by the underfill 13. For example, the left side and/or the right side of the retaining structure 12r may be entirely covered by the underfill 13.

The underfill 13 may be disposed between the surface 123 of the carrier 12c and the surface 113 of the electronic component 11. The underfill 13 may be overlapped with the surface 123 of the carrier 12c and the surface 113 of the electronic component 11 along a direction substantially perpendicular to the surface 123 and/or the surface 113.

The underfill 13 may be liquid at room temperature and may have a relatively low viscosity for easy flow and filling of spaces or voids. In some arrangements, the underfill 13 may include an epoxy-based underfill, a silicone-based underfill, or a polyimide-based underfill. The underfill 13 may be chosen based on functions such as reducing mechanical stress, improving thermal cycling performance, and protecting solder joints. For example, the underfill 13 may be designed to have a low modulus, low coefficient of thermal expansion (CTE), and to generate low stress during temperature cycling.

In some arrangements, an underfill flow prevention feature may be disposed around the underfill 13. The underfill flow prevention feature may include a plurality of raised features disposed around the mounting region of the electronic component 11 and the component 12.

The encapsulant 14 may be disposed over the carrier 10. The encapsulant 14 may cover or surround the electronic component 11, the component 12, and the underfill 13. The encapsulant 14 may have a surface (such as a top surface) 142. The surface 112 of the electronic component 11 may be at least partially exposed from the encapsulant 14. The surface 112 of the electronic component 11 and the surface 142 of the encapsulant 14 may be substantially coplanar or aligned.

In some arrangements, the surface (such as a top surface) 132 of the underfill 13 may be at least partially exposed from the encapsulant 14. The surface 132 of the underfill 13 and the surface 142 of the encapsulant 14 may be substantially coplanar or aligned. The surface 132 of the underfill 13 may be positioned at a higher elevation or farther away from the carrier 10 when compared to the carrier 12c.

For example, the electronic component 11 and component 12 may be positioned close enough to each other so that the underfill 13 can easily fill the space between them. This close proximity ensures a more efficient and uniform distribution of the underfill 13, which helps to improve adhesion between the electronic component 11 and component 12.

In some arrangements, the surface (such as a top surface) 12rt of the retaining structure 12r may be at least partially exposed from the encapsulant 14. The surface 12rt of the retaining structure 12 r and the surface 142 of the encapsulant 14 may be substantially coplanar or aligned.

In some arrangements, the encapsulant 14 may not contact the carrier 12c. For example, the encapsulant 14 may be spaced apart from the carrier 12c by the underfill 13. In some arrangements, the underfill 13 may climb onto the retaining structure 12r and surrounded by the encapsulant 14. For example, the encapsulant 14 may define a recessed portion and the underfill 13 may extend into the recessed portion of the encapsulant 14.

In some arrangements, the retaining structure 12r may have a damascene structure, with the top surface 12rt being coplanar with the underfill 13 and the encapsulant 14. In some arrangements, from a cross-sectional view, a side of the retaining structure 12r may be covered (such as entirely covered) by the underfill 13 and an opposite side of the retaining structure 12r may be covered (such as entirely covered) by the encapsulant 14.

In some arrangements, the encapsulant 14 may include an epoxy resin with fillers, a molding compound (e.g., an epoxy molding compound or another type of molding compound), a polyimide, a phenolic compound or material, a material with a silicone dispersed therein, or a combination thereof. In some arrangements, the encapsulant 14 may include a material different from that of the underfill 13.

For example, the encapsulant 14 may include a first Young's modulus, and the underfill 13 may include a second Young's modulus. A Young's modulus ratio (i.e., the ratio of the second Young's modulus to the first Young's modulus) may be greater than 1. For example, the flowability of the encapsulant 14 may be less than the flowability of the underfill 13.

FIG. 1B illustrates a partial enlarged view of an electronic device in accordance with some arrangements of the present disclosure. For example, the electronic device 1a may have the structure shown in FIG. 1B. In some arrangements, the structure in FIG. 1B is similar to the structure in the dotted box X in FIG. 1A, except that the underfill 13 defines or have a recessed portion 13h. The recessed portion 13h may be adjacent to the surface 12rt of the retaining structure 12r and/or the surface 112 of the electronic component 11. The encapsulant 14 may be disposed in the recessed portion 13h. The portion of the encapsulant 14 in the recessed portion 13h may have a surface substantially coplanar with the surface 12rt of the retaining structure 12r and/or the surface 112 of the electronic component 11.

For example, the underfill 13 may not completely fill the space between the retaining structure 12r and the electronic component 11, leaving a gap unfilled. The encapsulant 14 can be applied to occupy the remaining space. Subsequently, both the underfill 13 and the encapsulant 14 may undergo a planarization process, such as grinding or polishing, to create a coplanar top surface.

In some arrangements, the internal surface of the recessed portion 13h may have a local roughness greater than 1, such as about 2, 3, 4, 5, 6, 7, 8, 9, 10, and so on. The local roughness may be calculated by dividing the arithmetic average roughness (Ra) by the mean spacing (Sm). Ra is the arithmetic average of the absolute values of roughness amplitude, and Sm is the mean spacing between peaks of the roughness.

FIG. 1C illustrates a cross-sectional view of an electronic device 1c in accordance with some arrangements of the present disclosure. The electronic device 1c is similar to the electronic device 1a in FIG. 1A, except that the carrier 12c is omitted, potentially reducing manufacturing complexity and improving structural integrity. The retaining structure 12r may be connected to the carrier 10 through the adhesive layer 12g. For example, the adhesive layer 12g may directly contact the surface of the carrier 10, thereby providing a secure bond between the retaining structure 12r and the carrier 10.

In certain configurations, the length of the retaining structure 12r may exceed the length of the electronic component 11 in a direction that is substantially perpendicular to the carrier 10. For example, the surface 12rt of the retaining structure 12r may be aligned or leveled with the surface 112 of the electronic component 11. Additionally, an opposite surface (such as the surface 12rb) may extend beyond or protrude past the surface 111 of the electronic component 11.

FIG. 1D illustrates a partial enlarged view of an electronic device in accordance with some arrangements of the present disclosure. For example, the electronic device 1c may have the structure shown in FIG. 1D. In some arrangements, the structure in FIG. 1D is similar to the structure in the dotted box 2X in FIG. 1C, except that the adhesive layer 12g is replaced with a conductive pad 12a and an electrical contact 12s.

In some arrangements, from a top view, the conductive pad 12a may have a circular or rounded configuration or may exhibit a circular or rounded shape. For example, the conductive pad 12a may surround the opening 14h. For example, the conductive pad 12a may circle around the opening 14h. For example, the conductive pad 12a may completely encircle the opening 14h, providing a continuous boundary around it.

In some arrangements, the conductive pad 12a may consist of a copper (Cu) pad, while the electrical contact 12s may comprise a solder ball. The combination of the copper pad and solder ball connection offers excellent electrical conductivity, attributed to the metallic nature of the solder joint. Additionally, this connection provides a robust mechanical bond, which results from the solidification of the solder during the assembly process. This strong mechanical and electrical interface ensures reliable performance in various electronic applications, enhancing both signal integrity and structural stability.

FIG. 2A illustrates a cross-sectional view of an electronic device 2a in accordance with some arrangements of the present disclosure. The electronic device 2a is similar to the electronic device 1a in FIG. 1A, except that the electronic device 2a further includes the package 20 and the encapsulant 21.

The package 20 may be disposed over the component 12. The package 20 may be disposed in the opening 14h. The package 20 may be surrounded by the retaining structure 12r. The package 20 and the component 12 may be substantially overlapped in the direction substantially perpendicular to the surface 122 of the carrier 12c.

The package 20 may be electrically connected to the component 12, and the electrical connections may be attained by way of solder bonding, Cu-to-Cu bonding, wire bonding, or hybrid bonding. For example, the package 20 may be electrically connected with the component 12 through electrical contacts 20e.

The package 20 may include a memory package, such as a dynamic random access memory (DRAM) package, a static RAM (SRAM) package, a read-only memory (ROM) package, a flash memory package, a magnetoresistive RAM (MRAM) package, etc. However, the inventive concept is not limited thereto. For example, the package 20 may be or include other types of packages, such as a transceiver package, a processing package, a networking package, a voltage regulating package (which may provide a regulated voltage), etc.

In some arrangements, the package 20 may include a carrier 20c, a component 20a, and an encapsulant 20m. The carrier 20 c may be configured to provide structural support for the component 20 a and the encapsulant 20m. The component 20 a may include one or more memory dies. For example, FIG. 2A may illustrate only the outermost memory die, providing a focused view of its structure and layout without depicting the underlying or adjacent dies. In some arrangements, the component 20a may include other types of dies. The encapsulant 20m may be disposed over the carrier 20c and covering the component 20a.

The encapsulant 20m may include a material as listed above with respect to the encapsulant 14. In some arrangements, the encapsulant 20m may include a material different from that of the encapsulant 14. In some arrangements, the encapsulant 20m and the encapsulant 14 may include the same material having a distinguishable interface therebetween.

The encapsulant 21 may fill the gap or space within the opening 14h after the package 20 has been placed inside the opening 14h. The encapsulant 21 may cover the package 20. This filling process helps to ensure a secure fit, providing structural support and protection for the package 20, while also preventing the ingress of contaminants such as dust or moisture.

The encapsulant 21 may include a material as listed above with respect to the encapsulant 14. In some arrangements, the encapsulant 21 may include a material different from that of the encapsulant 14. In some arrangements, the encapsulant 21 and the encapsulant 14 may include the same material having a distinguishable interface therebetween.

In some arrangements, the encapsulant 21 and the encapsulant 20m may define or include an interface or a boundary. For example, an interface (such as a void-free interface) may be present at the junction where the encapsulant 21 meets the encapsulant 20m.

The encapsulant 21 may have a surface (such as a top surface) 212. The surface 142 of the encapsulant 14, the surface 112 of the electronic component 11, the surface 132 of the underfill 13, the surface 12rt of the retaining structure 12r, and the surface 212 of the encapsulant 21 may be substantially coplanar or aligned.

In some arrangements, from a cross-sectional view, the retaining structure 12r may be covered by the underfill 13, the encapsulant 14, and the encapsulant 21. For example, the internal surface of the retaining structure 12r may be covered by the encapsulant 21, while the opposite external surface of the retaining structure 12r may be covered by the underfill 13.

FIG. 2B illustrates a cross-sectional view of an electronic device 2b in accordance with some arrangements of the present disclosure. The electronic device 2b is similar to the electronic device 2a in FIG. 2A, except that the electronic device 2b further includes a heat dissipating element 22 connecting thereto through an adhesive layer 22g, such as a heat dissipating gel. The heat dissipating element 22 may include a heat transfer unit. The heat dissipating element 22 may include one or more thermal conductive films. The heat dissipating element 22 may have a relatively high thermal conductivity. For example, the heat dissipating element 22 may include copper (Cu), aluminum (Al), graphite, ceramics, etc. The heat dissipating element 22 may include a block, a pipe, a sink, a fin, or other shapes.

In some arrangements, a width 22w of the heat dissipating element 22 may be less than a width 14w of the encapsulant 14. For example, a portion of the adhesive layer 22g may be uncovered by the heat dissipating element 22. For example, a width (substantially equal to the width 14w) of the adhesive layer 22g may be greater than the width 22w of the heat dissipating element 22. For example, an adhesive coverage of the adhesive layer 22g may be greater than a coverage of the heat dissipating element 22.

FIG. 2C illustrates a cross-sectional view of an electronic device 2c in accordance with some arrangements of the present disclosure. The electronic device 2c is similar to the electronic device 2a in FIG. 2A, except that the electronic device 2c further includes a shielding layer 23.

The shielding layer 23 may include a substantially conformal layer or conformal shield. The shielding layer 23 may be formed by a plating process. The shielding layer 23 may be disposed on the surface 142 of the encapsulant 14, the surface 112 of the electronic component 11, the surface 132 of the underfill 13, the surface 12rt of the retaining structure 12r, and the surface 212 of the encapsulant 21.

The shielding layer 23 may be electrically connected to a grounding element of the carrier 10. In some arrangements, the shielding layer 23 may include a conductive thin film composed of materials such as copper, aluminum, or conductive polymers, which facilitate effective electrical conductivity. Additionally, the shielding layer 23 may be designed to provide electrostatic discharge (ESD) protection, thereby safeguarding sensitive components within the electronic device 2g from potential damage caused by sudden electrical surges or static electricity.

FIG. 2D illustrates a partial enlarged view of an electronic device in accordance with some arrangements of the present disclosure. For example, the electronic device 2a may have the structure shown in FIG. 2D. In some arrangements, the structure in FIG. 2D is similar to the structure in the dotted box 3X in FIG. 2A, except that the package 20 may be exposed from the encapsulant 21. For example, the encapsulant 20m may have a surface (such as a top surface) 20m2 at least partially exposed from the encapsulant 21.

For example, the package 20 may have a height that exceeds the depth of the opening defined by the retaining structure 12r. For example, the package 20 may extend beyond or protrude past the surface 12rt of the retaining structure 12r. Specifically, the surface 20m2 of the encapsulant 20m may be positioned at a higher elevation or farther away from the carrier 10, as illustrated in FIG. 2A, when compared to the surface 12rt of the retaining structure 12r.

The encapsulant 21 may fill the gap or space between the package 20 and the retaining structure 12r. The encapsulant 21 may have a surface 213 connecting between the surface 20m2 of the encapsulant 20m and the surface 12rt of the retaining structure 12r. In some arrangements, the surface 213 may be tilted, inclined, or angled with respect to the surface 20m2 of the encapsulant 20m. In some arrangements, the surface 213 may be tilted, inclined, or angled with respect to the surface 12rt of the retaining structure 12r. In some arrangements, from a cross-sectional perspective, the surface 213 may exhibit a curved or uneven profile rather than a straight line.

FIG. 2E illustrates a partial enlarged view of an electronic device in accordance with some arrangements of the present disclosure. For example, the electronic device 2b may have the structure shown in FIG. 2E. In some arrangements, the structure in FIG. 2E is similar to the structure in the dotted box 3X in FIG. 2B, except that the package 20 may be exposed from the encapsulant 21 and covered by the adhesive layer 22g. In some arrangements, the surface 213 of the encapsulant 21 may be covered or contacted by the adhesive layer 22g.

In some arrangements, the encapsulant 21 and the adhesive layer 22g may define or include an interface or a boundary. For example, an interface or a boundary may be present at the junction where the encapsulant 21 meets the adhesive layer 22g. In some arrangements, the encapsulant 21 and the adhesive layer 22g may define or include an uneven interface.

In some arrangements, the adhesive layer 22g may have an uneven thickness or may exhibit variations in thickness. For example, the portion of the adhesive layer 22g that overlaps with the package 20 may be thinner compared to other the other portions of the adhesive layer 22g. For example, the adhesive layer 22g may have a substantially planar surface facing the heat dissipating element 22, and a non-planar or irregular surface facing the package 20.

The substantially planar surface may facilitate the subsequent process of placing the heat dissipating element 22, ensuring uniform contact and efficient heat transfer. The non-planar or irregular surface may accommodate surface irregularities of the package 20 or provide enhanced mechanical bonding

FIG. 2F illustrates a partial enlarged view of an electronic device in accordance with some arrangements of the present disclosure. For example, the electronic device 2c may have the structure shown in FIG. 2F. In some arrangements, the structure in FIG. 2F is similar to the structure in the dotted box 3X in FIG. 2C, except that the package 20 may be exposed from the encapsulant 21 and covered by the shielding layer 23. In some arrangements, the surface 213 of the encapsulant 21 may be covered or contacted by the shielding layer 23.

In some arrangements, the encapsulant 21 and the shielding layer 23 may define or include an interface or a boundary. For example, an interface or a boundary may be present at the junction where the encapsulant 21 meets the shielding layer 23. In some arrangements, the encapsulant 21 and the shielding layer 23 may define or include an uneven interface.

In some arrangements, the shielding layer 23 may have an uneven thickness or may exhibit variations in thickness. For example, the portion of the shielding layer 23 that overlaps with the package 20 may be thinner compared to other the other portions of the shielding layer 23. For example, the shielding layer 23 may have a substantially planar surface facing the heat dissipating element 22, and a non-planar or irregular surface facing the package 20.

The substantially planar surface may facilitate the subsequent process of sputtering the shielding layer 23, improving the adhesion and coverage of the shielding layer 23. The non-planar or irregular surface may accommodate surface irregularities of the package 20 or provide enhanced mechanical bonding.

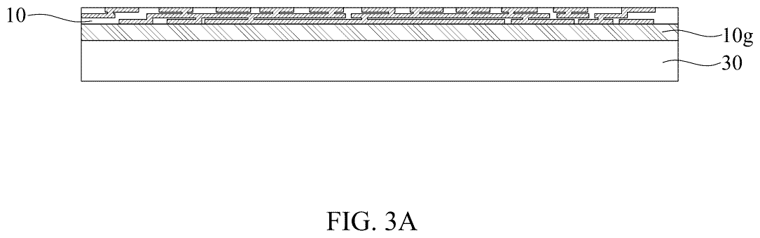

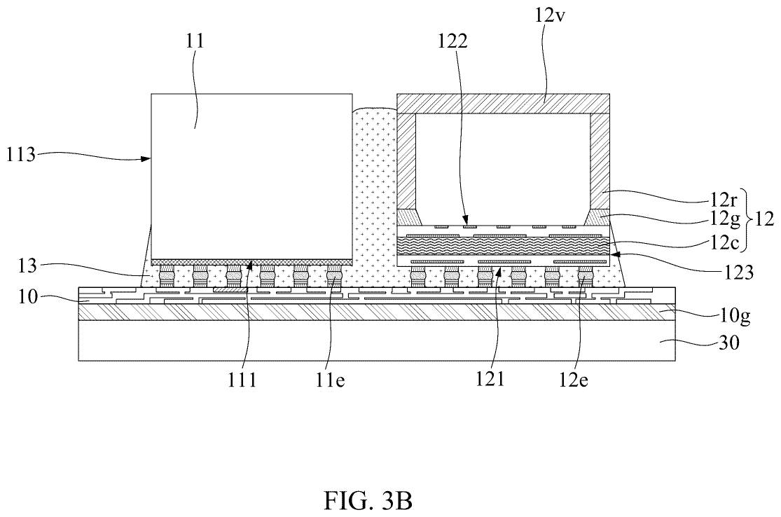

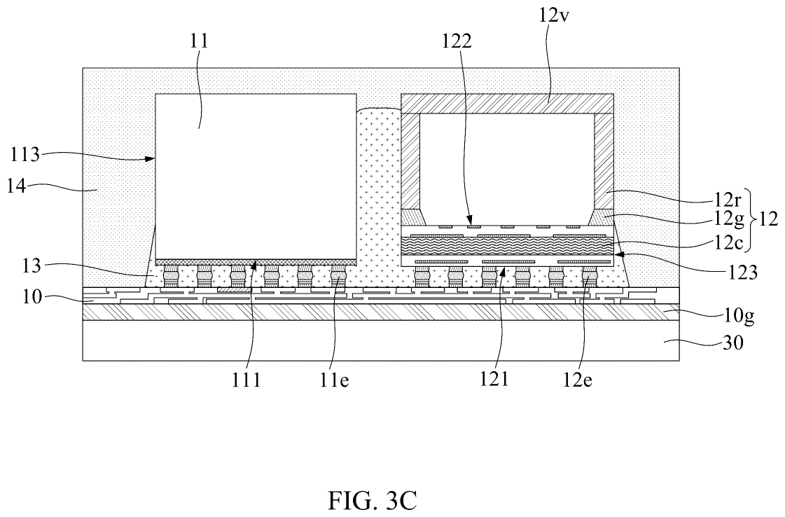

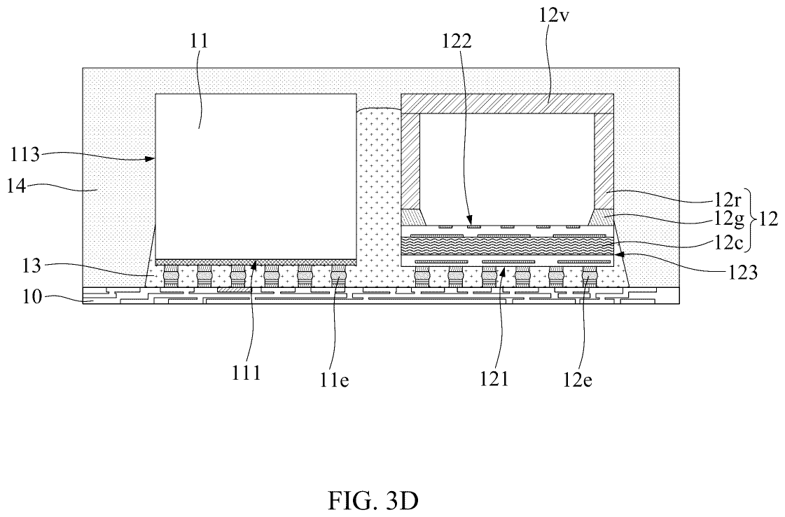

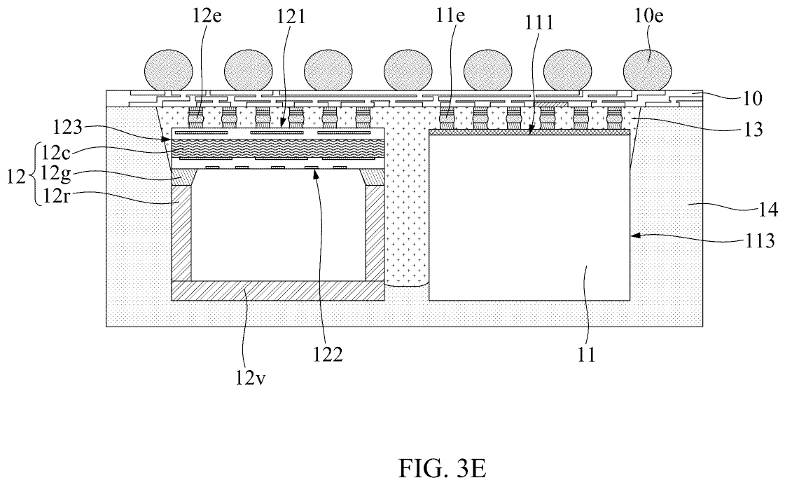

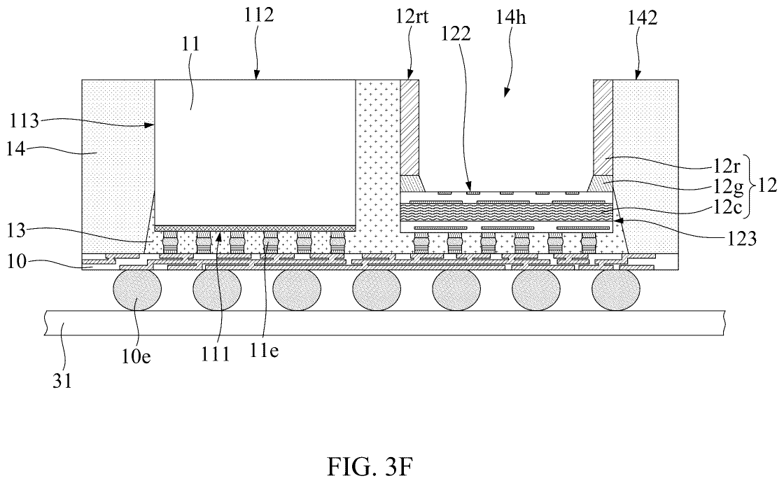

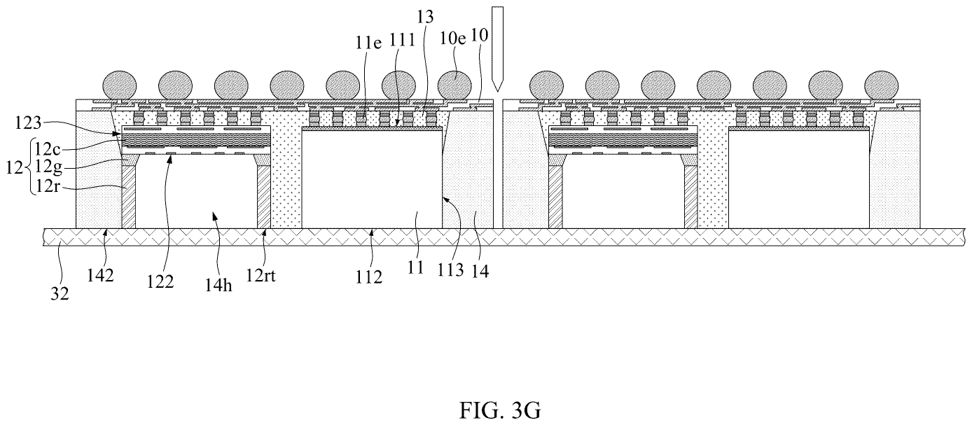

FIGS. 3A, 3B, 3C, 3D, 3E, 3F, and 3G are cross-sections of one or more stages of a method of manufacturing an electronic device in accordance with some arrangements of the present disclosure. At least some of these figures have been simplified to facilitate better understanding of the aspects of the present disclosure. In some arrangements, the electronic device 1a may be manufactured through the steps illustrated in FIGS. 3A, 3B, 3C, 3D, 3E, 3F, and 3G.

Referring to FIG. 3A, a temporary carrier 30 may be provided (e.g., manufactured or obtained). The temporary carrier 30 may be a glass carrier, a metal carrier, a ceramic carrier, or other suitable carriers. The temporary carrier 30 may include a panel, and the size thereof can be approximately 300 mm square, 500 mm square, 600 mm square, or larger. For example, the electronic device 1a may be implemented using a panel level packaging (PLP) process. In the PLP process, a panel is used to fabricate multiple semiconductor packages simultaneously. Compared to conventional wafer-level packaging (WLP), the use of a panel allows for greater production throughput and improved material utilization, as a result of the increased substrate size. The rectangular substrate is typically formed of an organic laminate material or a glass-based substrate, and may include pre-defined cutting streets (saw lanes) along rows and columns to facilitate singulation after encapsulation and other back-end processes.

The carrier 10 may be formed over the temporary carrier 30. The carrier 10 may be attached to the temporary carrier 30 through an adhesive layer 10g. The adhesive layer 10a may include a die attach film (DAF), a glue, a bonding layer, an underfill, or another suitable material.

In some arrangements, due to the rectangular geometry of the panel, electroplating during RDL formation may result in charge accumulation at the corners, leading to unique microstructural effects on the routing lines near the panel edges—effects that do not occur on circular wafers. To compensate for plating non-uniformity at the panel corners, dummy structures may be densely distributed in these regions. Furthermore, the panel's cutting streets are typically aligned parallel or perpendicular to the panel edges, which is structurally distinct from the dicing paths on wafers.

Referring to FIG. 3B, the electronic component 11 and the component 12 may be disposed over the temporary carrier 30. The component 12 further includes a cover 12v disposed over the retaining structure 12r. The component 12 may define a hollow space.

In some arrangements, more than two electronic devices may be placed on the temporary carrier 30 in a batch and subjected to similar or identical processes in the manufacturing method. For example, the electronic component 11 may be arranged in an N×M array. For example, the component 12 may be arranged in an N×M array. For example, the sidewalls of the electronic components 11 may be aligned with the sidewalls of the components 12 forming a symmetric array. For example, the relative displacements between the sidewalls of the electronic components 11 and the sidewalls of the components 12 may be substantially equal.

In some arrangements, compared to WLP, PLP is based on a rectangular panel substrate on which multiple components are arranged in an N×M array, with each row and each column containing the same number of components. This uniform grid arrangement is a characteristic feature of PLP and differs from WLP, where die density is typically higher at the wafer center and lower at the periphery. For example, WLP includes a central region including a relatively higher density of dies and a peripheral region including a relatively lower density of dies. In PLP, the outermost row and the outermost column may share a single component located at the panel corner —a layout that is uncommon on a circular wafer.

The underfill 13 may be disposed over the temporary carrier 30. The underfill 13 may connect the electronic component 11 and the component 12 to the temporary carrier 30. For example, the electronic component 11 and the electronic component 12 may be positioned at specific locations on a support structure within a dispensing system during the application of the underfill material 13. In certain configurations, an image of the underfill 13 can be captured in situ, that is, directly during the dispensing process. This real-time imaging allows for precise monitoring of the underfill application. Using the captured image, the fillet width of the underfill can be accurately measured. Based on these measurements, a plurality of threshold levels for the fillet width can be established, which may be used to ensure quality control and consistency in the dispensing process.

In some arrangements, the underfill 13 may be formed through anisotropic deposition techniques. Unlike isotropic deposition, in which material is deposited uniformly in all directions, anisotropic deposition produces a non-uniform film or structure by selectively enhancing deposition in targeted areas.

Referring to FIG. 3C, the encapsulant 14 may be disposed over the carrier 10 to cover the electronic component 11, the component 12, and the underfill 13. In some arrangements, the encapsulant 14 may be formed by a molding technique, such as transfer molding, injection molding, or compression molding. The cover 12v may prevent the encapsulant 14 from flowing into the hollow space of the component 12.

Referring to FIG. 3D, the temporary carrier 30 and the adhesive layer 10g may be removed, and the carrier 10 may be exposed.

Referring to FIG. 3E, the electrical contact 10e may be formed over the carrier 10.

Referring to FIG. 3F, the structure obtained from the operation of FIG. 3E may be disposed over a temporary carrier 31. A planarization operation or a grinding operation may be performed to remove a portion (such as the cover 12v) of the component 12 to form the opening 14h. A portion of the encapsulant 14 is also removed to expose the surface 112 of the electronic component 11. The planarization operation or grinding operation may include an abrasive machining process that uses a grinding wheel or grinder, a chemical mechanical planarization (CMP) process, an etching process, or a laser-based process (such as a laser direct ablation (LDA) process, a laser drilling process, a laser cutting process).

Referring to FIG. 3G, the structure obtained from the operation of FIG. 3F may be disposed over a dicing tape 32. A singulation operation may be performed. The electronic device assembly may be singulated or separated into a plurality of individual units or segmented parts in a singulation operation. In some arrangements, the singulation operation may be applied using a saw blade or laser cutting tool. In some arrangements, the product may be shipped to a different production line for the placement of the package 20. Compared to an embodiment that does not include the component 12, the presence of the component 12 can enhance the overall structural strength and durability of the product.

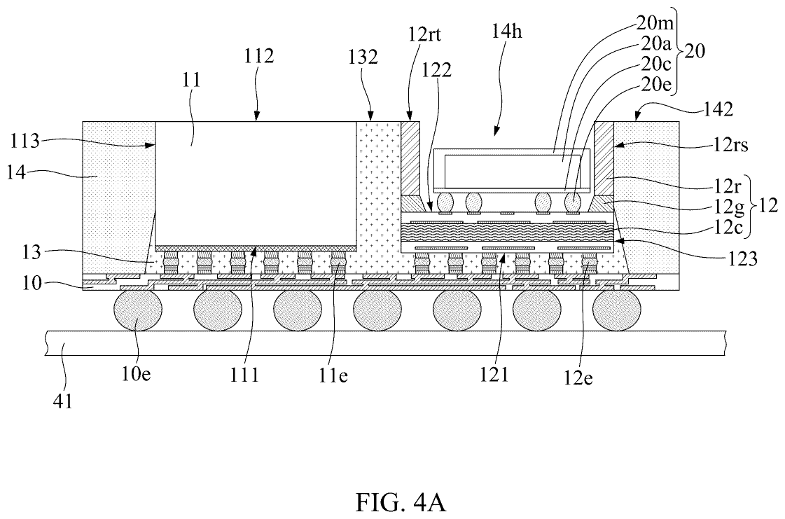

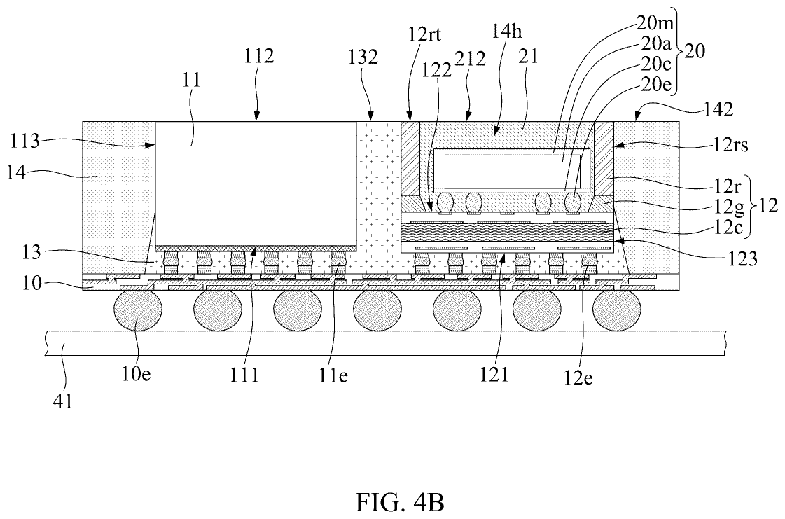

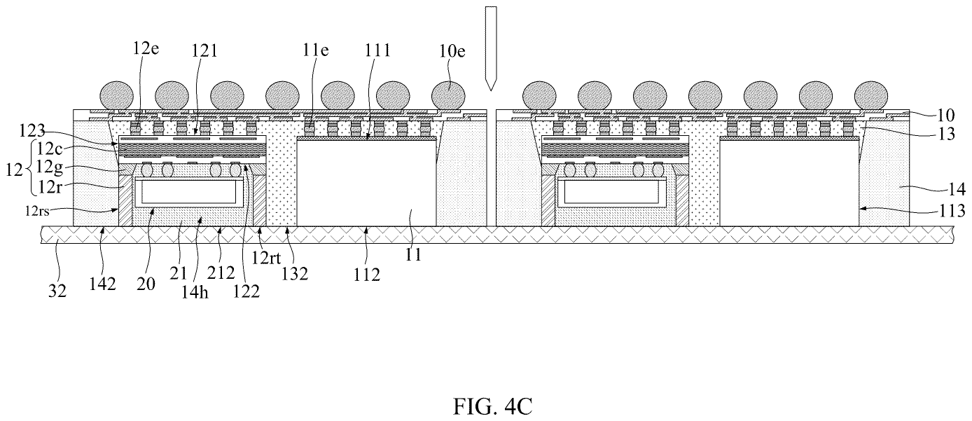

FIGS. 4A, 4B, and 4C are cross-sections of one or more stages of a method of manufacturing an electronic device in accordance with some arrangements of the present disclosure. At least some of these figures have been simplified to facilitate better understanding of the aspects of the present disclosure. In some arrangements, the electronic device 2a may be manufactured through the steps illustrated in FIGS. 4A, 4B, and 4C.

Referring to FIG. 4A, which is subsequent to the operation in FIG. 3F, the structure obtained from the operation of FIG. 3F may be disposed over a temporary carrier 41. The package 20 may be disposed over the component 12 and in the opening 14h. The package 20 may be surrounded by the retaining structure 12r. In some arrangements, an electrical test can be performed on the carrier 10 before mounting the package 20.

Conventionally, the package (such as a memory package) is molded together with the IC die within the encapsulant. During subsequent processing steps, the package is at risk of being damaged. This conventional approach introduces significant challenges, as any damage incurred cannot be rectified by removing or replacing the package after the molding process. Consequently, this conventional approach often results in higher manufacturing costs and lower production yields, as defective packages lead to increased waste and rework.

According to some arrangements of the present disclosure, the invention employs the component 12 placed on a designated RDL area for die placement, followed by molding and creating an opening to expose pads of the component 12. This allows electrical testing of the RDL before die attachment, thereby facilitating early defect detection, reducing costs, and improving yield.

In some arrangements, an electrical test may be conducted after the package 20 has been placed within the opening 14h. If either the package 20 or the carrier 10 is found to be defective during this test, the method includes disengaging and removing the package 20 from the opening to allow for replacement or further inspection.

In some arrangements, the package 20 or the carrier 10 are controlled to operate in a repair mode, wherein the testing signal is redirected away from the damaged pathway and routed through an alternative route instead.

Referring to FIG. 4B, the encapsulant 21 may fill the gap or space within the opening 14h after the package 20 has been placed inside the opening 14h. In some arrangements, the encapsulant 21 may be formed by a molding technique, such as transfer molding, injection molding, or compression molding. A planarization operation or a grinding operation may be performed to remove a portion of the encapsulant 21.

Referring to FIG. 4C, the structure obtained from the operation of FIG. 4B may be disposed over a dicing tape 42. A singulation operation may be performed. The electronic device assembly may be singulated or separated into a plurality of individual units in a singulation operation. In some arrangements, the singulation operation may be applied using a saw blade or laser cutting tool.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a metal-containing layer;
a retaining structure disposed over the metal-containing layer, wherein the retaining structure defines an opening over the metal-containing layer to accommodate a memory package; and
an underfill connecting the metal-containing layer and the retaining structure, wherein the underfill contacts a sidewall of the retaining structure.

2. The electronic device of claim 1, wherein a top surface of the underfill and a top surface of the retaining structure are substantially coplanar.

3. The electronic device of claim 2, further comprising:
an encapsulant disposed over the metal-containing layer and covering the retaining structure and the underfill, wherein a top surface of the encapsulant and the top surface of the retaining structure are substantially coplanar.

4. The electronic device of claim 1, further comprising:
a carrier disposed between the retaining structure and the metal-containing layer, wherein a top surface of the underfill is at a higher elevation than the carrier with respect to the metal-containing layer.

5. The electronic device of claim 4, wherein the retaining structure is disposed on a periphery region of the carrier and encircle the opening.

6. The electronic device of claim 1, further comprising:
a chip disposed over the metal-containing layer and in adjacent to the retaining structure, wherein the underfill defines a recessed portion between the chip and the retaining structure.

7. The electronic device of claim 6, further comprising:
an encapsulant disposed in the recessed portion, wherein the encapsulant has a surface substantially coplanar with a top surface of the retaining structure.

8. The electronic device of claim 1, further comprising:
a memory package disposed in the opening, wherein the memory package extends beyond a top surface of the retaining structure.

9. The electronic device of claim 8, further comprising:
an encapsulant disposed in a gap between the memory package and the retaining structure, wherein the encapsulant has an uneven surface.

10. The electronic device of claim 8, further comprising:
a heat dissipating element connected to the memory package through an adhesive layer, wherein the adhesive layer has a substantially planar surface facing the heat dissipating element and a non-planar surface facing the memory package.

11. An electronic device, comprising:
a metal-containing layer;
a chip disposed over the metal-containing layer and having a backside surface;
a retaining structure disposed over the metal-containing layer and adjacent to the chip; and
an underfill connecting the metal-containing layer, the chip, and the retaining structure,
wherein a top surface of the retaining structure is substantially aligned with the backside surface of the chip.

12. The electronic device of claim 11, wherein a top surface of the underfill and the top surface of the retaining structure are substantially aligned.

13. The electronic device of claim 11, further comprising:
a memory package surrounded by the retaining structure; and
an encapsulant covering the memory package and having a top surface substantially aligned with the top surface of the retaining structure.

14. The electronic device of claim 13, wherein an internal surface of the retaining structure is covered by the encapsulant and an opposite external surface of the retaining structure is covered by the underfill from a cross-sectional view.

15. The electronic device of claim 11, further comprising:
a memory package surrounded by the retaining structure; and
an encapsulant covering the memory package and having a surface inclined with respect to the top surface of the retaining structure.

16. The electronic device of claim 15, further comprising:
a heat dissipating element connecting to the memory package through an adhesive layer, wherein the adhesive layer has an uneven thickness.

17. The electronic device of claim 16, wherein a portion of the adhesive layer overlapping the memory package is thinner compared to a portion of the adhesive layer overlapping the retaining structure.

18. A method for manufacturing an electronic device, comprising:
providing a metal-containing layer;
disposing a retaining structure over the metal-containing layer;
forming a first encapsulant covering the retaining structure; and
partially removing the retaining structure to form an allocate space defined by the retaining structure.

19. The method of claim 18, further comprising:
disposing a chip over the metal-containing layer in adjacent to the retaining structure.

20. The method of claim 18, further comprising:
after partially removing the retaining structure, disposing a memory package in the allocate space surrounded by the retaining structure.
